(19) United States
(12) Patent Application Publication
(10) Pub. No.: US 2010/0294357 A1
(43) Pub. Date: Nov. 25, 2010

(54) Solar Cell and Method for Manufacturing the Same

(76) Inventor: Deoc Hwan HYUN, Yongin-si (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/782,676

(22) Filed: May 18, 2010

(30) Foreign Application Priority Data
May 19, 2009 (KR) 10-2009-0043695

(51) Int. Cl. H01L 31/0236; H01L 31/18

(52) U.S. Cl. 136/256; 438/71; 257/E31.13

(57) ABSTRACT

A solar cell capable of improving efficiency, and a method for manufacturing the same is disclosed, wherein the method for manufacturing the solar cell comprises forming seeds in a predetermined surface portion of a semiconductor substrate doped with a first dopant through the use of silicon source gas; forming an irregularity structure on the semiconductor substrate by growing the seeds through a heat-treatment process; forming a first semiconductor layer doped with a second dopant in the semiconductor substrate with the irregularity structure, wherein the second dopant is different from the first dopant; and forming a front electrode at one side of the semiconductor substrate, the front electrode electrically connected to the first semiconductor layer.

### CROSS REFERENCE TO RELATED APPLICATIONS

This application claims the benefit of the Korean Patent Application No. P2009-0043695 filed on May 19, 2009, which is hereby incorporated by reference as if fully set forth herein.

### BACKGROUND OF THE INVENTION

1. Field of the Invention

The present invention relates to a solar cell, and more particularly, to a solar cell capable of improving efficiency, and a method for manufacturing the same.

2. Discussion of the Related Art

A solar cell with a property of semiconductor converts a light energy into an electric energy.

A structure and principle of the solar cell will be briefly explained as follows. The solar cell is provided with a photoelectric conversion part of a PN junction structure where a P(positive)-type semiconductor makes a junction with an N(negative)-type semiconductor. When a solar ray is incident on the photoelectric conversion part of the solar cell, holes(+) and electrons(−) are generated in the semiconductor owing to the energy of solar ray. By an electric field generated in a PN junction area, the holes(+) are drifted toward the P-type semiconductor, and the electrons(−) are drifted toward the N-type semiconductor, whereby an electric power is produced with an occurrence of electric potential.

Generally, a cell efficiency of the solar cell may be measured by an efficiency of converting the light energy into the electric energy, wherein a value of the cell efficiency can be a proportion of electricity output of the solar cell in relation to a light-incidence amount, which can be shown as a percentage (%).

Accordingly, studies for improving the cell efficiency of solar cell are in progress, and there are continuous needs for technical developments to improve the cell efficiency of solar cell.

### SUMMARY OF THE INVENTION

Accordingly, the present invention is directed to a solar cell and a method for manufacturing the same that substantially obviates one or more problems due to limitations and disadvantages of the related art.

An advantage of the present invention is to provide a solar cell capable of improving cell efficiency, and a method for manufacturing the same.

Additional features and aspects of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these and other advantages and in accordance with the purpose of the invention, as embodied and broadly described herein, there is provided a method for manufacturing a solar cell comprising forming seeds on a predetermined surface portion of a semiconductor substrate doped with a first dopant through the use of silicon source gas; forming an irregularity structure on the semiconductor substrate by growing the seeds through a heat-treatment process; forming a first semiconductor layer doped with a second dopant in the semiconductor substrate with the irregularity structure, wherein the second dopant is different from the first dopant; and forming a front electrode at one side of the semiconductor substrate, the front electrode electrically connected to the first semiconductor layer.

The first semiconductor layer is formed in the semiconductor substrate and upper surface of the irregularity structure by doping the semiconductor substrate and upper surface of the irregularity structure with the second dopant.

The heat-treatment process may be carried out at a temperature of 600 to 700° C. for 5 to 90 seconds so as to form the irregularity structure with curved-line shapes.

The heat-treatment process may be carried out at a temperature of 600 to 700° C. for 90 to 120 seconds so as to form the irregularity structure with curved-line shapes having neck portions.

In another aspect of the present invention, a method for manufacturing a solar cell comprises forming a first-irregularity structure on a surface of a semiconductor substrate doped with a first dopant; forming a second-irregularity structure in the first-irregularity structure; forming a first semiconductor layer doped with a second dopant in the semiconductor substrate with the first-irregularity structure and second-irregularity structure, wherein the second dopant is different from the first dopant; and forming a front electrode at one side of the semiconductor substrate, the front electrode electrically connected to the first semiconductor layer.

The first semiconductor layer is formed in the semiconductor substrate and upper surfaces of the first-irregularity structure and second-irregularity structure by doping the semiconductor substrate and upper surfaces of the first-irregularity structure and second-irregularity structure with the second dopant.

In addition, the method comprises forming a reflection-preventing layer of silicon nitride or silicon oxide on the first semiconductor layer; wherein the front electrode is electrically connected to the first semiconductor layer through the reflection-preventing layer.

In this case, the first dopant is a P-type or N-type dopant.

Furthermore, the method comprises forming a rear electrode at the other side of the semiconductor substrate; and forming a second semiconductor layer at the other side of the semiconductor substrate through a heat-treatment process, the second semiconductor layer doped with the first dopant whose concentration is relatively higher than that of the first dopant used for doping the semiconductor substrate; wherein the rear electrode is electrically connected to the semiconductor substrate through the second semiconductor layer.

The first-irregularity structure is formed by wet etching or dry etching process.

The first-irregularity structure is formed in a mountain shape.

Also, the process of forming the second-irregularity structure in the first-irregularity structure comprises forming seeds in the first-irregularity structure through the use of silicon source gas; and forming the second-irregularity structure by growing the seed in the first-irregularity structure through a heat-treatment process.

The silicon source gas is SiH₄ or Si₂H₆.

The heat-treatment process may be carried out at a temperature of 600 to 700° C. for 5 to 90 seconds so as to form the second-irregularity structure with curved-line shapes.

The heat-treatment process may be carried out at a temperature of 600 to 700° C. for 90 to 120 seconds so as to form the second-irregularity structure with curved-line shapes having neck portions.

In another aspect of the present invention, a solar cell comprises a semiconductor substrate doped with a first dopant; a first-irregularity structure on the semiconductor substrate; a second-irregularity structure in the first-irregularity structure; a first semiconductor layer doped with a second dopant in the semiconductor substrate with the first-irregularity structure and second-irregularity structure, wherein the second dopant is different from the first dopant; and a front electrode electrically connected to the first semiconductor layer.

In addition, the solar cell comprises a reflection-preventing layer of silicon nitride or silicon oxide on the first semiconductor layer; wherein the front electrode is electrically connected to the first semiconductor layer through the reflection-preventing layer.

The reflection-preventing layer is formed in such a way that the reflection-preventing layer is provided with an irregularity structure which is identical in position and shape to the irregularity structure in the first semiconductor layer.

Also, the first dopant is a P-type or N-type dopant.

In addition, the solar cell further comprises a rear electrode at the other side of the semiconductor substrate; and a second semiconductor layer at the other side of the semiconductor substrate through a treat-treatment process, the second semiconductor layer doped with the first dopant whose concentration is relatively higher than that of the first dopant used for doping the semiconductor substrate; wherein the rear electrode is electrically connected to the semiconductor substrate through the second semiconductor layer.

The first-irregularity structure is formed in a mountain shape.

Also, the second-irregularity structure protruding from the surface of the first-irregularity structure is formed in curved-line shapes or curved-line shapes having neck portions.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross section view illustrating a solar cell according to the first embodiment of the present invention;

FIG. 2 is a cross section view illustrating a solar cell according to the second embodiment of the present invention;

FIGS. 3A to 3J are cross section views illustrating a method for manufacturing the solar cell according to the first embodiment of the present invention;

FIGS. 4A to 4C are cross section views illustrating a procedure for forming an irregularity structure in the method for manufacturing the solar cell according to the first embodiment of the present invention; and

FIGS. 5A to 5H are cross section views illustrating a method for manufacturing the solar cell according to the second embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a solar cell according to the present invention and a method for manufacturing the same will be explained with reference to the accompanying drawings.

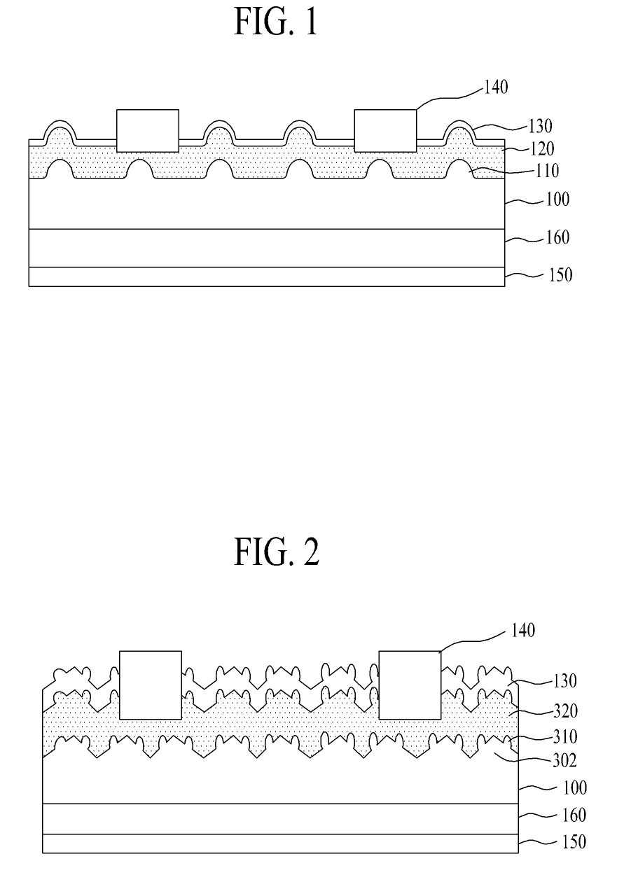

FIG. 1 is a cross section view illustrating a solar cell according to the first embodiment of the present invention.

As shown in FIG. 1, the solar cell according to the first embodiment of the present invention includes a P-type semiconductor layer 100, an N-type semiconductor layer 120, a reflection-preventing layer 130, a front electrode 140, and a rear electrode 150.

The P-type semiconductor layer 100 may be a P-type semiconductor substrate doped with a first dopant, for example, P-type dopant.

The N-type semiconductor layer 120 doped with a second dopant, for example, N-type dopant is formed in the P-type semiconductor layer 100. Also, an irregularity structure 110 is formed in an upper surface of the N-type semiconductor layer 120, whereby the upper surface of the N-type semiconductor layer 120 becomes uneven.

The irregularity structure 110 is formed by growing silicon-based seeds in a surface of the P-type semiconductor substrate through a heat-treatment process using a source gas such as SiH₄ or Si₂H₆. At this time, a shape of the irregularity structure 110 may vary according to a time period of the heat-treatment process to be treated, for example, hemispheric-shaped irregularity structure, or curved-line irregularity structure with neck portions.

The reflection-preventing layer 130 is formed on the N-type semiconductor layer 120, wherein the reflection-preventing layer 130 prevents a reflection of incident light. At this time, the reflection-preventing layer 130 is formed in such a way that an upper surface of the reflection-preventing layer 130 is identical in shape to the upper surface of the N-type semiconductor layer 120. That is, the shape in the upper surface of the reflection-preventing layer 130 depends on the irregularity structure 110 in the surface of the P-type semiconductor layer 100.

The front electrode 140 is formed on the reflection-preventing layer 130, and is electrically connected to the N-type semiconductor layer 120 through a heat-treatment process.

The rear electrode 150 is formed on a rear surface of the P-type semiconductor substrate, and is electrically connected to the P-type semiconductor layer 100 through a heat-treatment process.

In more detail, under the circumstance that the rear electrode 150 is formed on the rear surface of the P-type semiconductor substrate after forming the front electrode 140 on the reflection-preventing layer 130, the heat-treatment process is carried out at a high temperature more than 850° C. Thus, according as a front electrode material permeates into the N-type semiconductor layer 120 through the reflection-preventing layer 130, the front electrode 140 is electrically connected to the N-type semiconductor layer 120. Also, according as a rear electrode material permeates into a lower surface of the P-type semiconductor layer 100, a P⁺-type semiconductor layer 160 is formed in the rear surface of the P-type semiconductor substrate, whereby the rear electrode 150 is electrically connected to the P-type semiconductor layer 100 through the P⁺-type semiconductor layer 160.

In the solar cell according to the first embodiment of the present invention, the hemispheric-shaped irregularity structure 110 is formed by growing the silicon-based seeds, to thereby result in lowering of light-reflection ratio, and improvement of cell efficiency by the increased light dispersion.

FIG. 2 is a cross section view illustrating a solar cell according to the second embodiment of the present invention.

As shown in FIG. 2, the solar cell according to the second embodiment of the present invention includes a P-type semiconductor layer 100, an N-type semiconductor layer 320, a reflection-preventing layer 130, a front electrode 140, and a rear electrode 150. Except the N-type semiconductor layer 320, the solar cell according to the second embodiment of the present invention is identical in structure to the aforementioned solar cell according to the first embodiment of the present invention, whereby a detailed explanation for the same parts will be omitted.

The N-type semiconductor layer 320 doped with a second dopant, for example, N-type dopant is formed on the P-type semiconductor layer 100. At this time, a first-irregularity structure 302 is formed in an upper surface of the P-type semiconductor layer 100; and a second-irregularity structure 310 is formed in the first-irregularity structure 302.

The first-irregularity structure 302 may be formed in a mountain-shaped irregularity structure. This mountain-shaped first-irregularity structure 302 may be formed by a wet-etching or dry-etching process.

The second-irregularity structure 310 is formed by growing silicon-based seeds on a surface of the P-type semiconductor layer 100 through a heat-treatment process using a source gas such as SiH₄ or Si₂H₆. At this time, a shape of the second-irregularity structure 310 may vary according to a time period of the heat-treatment process to be treated, for example, hemispheric-shaped irregularity structure, or curved-line irregularity structure with neck portions.

In the solar cell according to the second embodiment of the present invention, a surface area of the N-type semiconductor layer 320 increases owing to the first-irregularity structure 302 and second-irregularity structure 310, to thereby result in lowering of light-reflection ratio, and improvement of cell efficiency by the increased light dispersion.

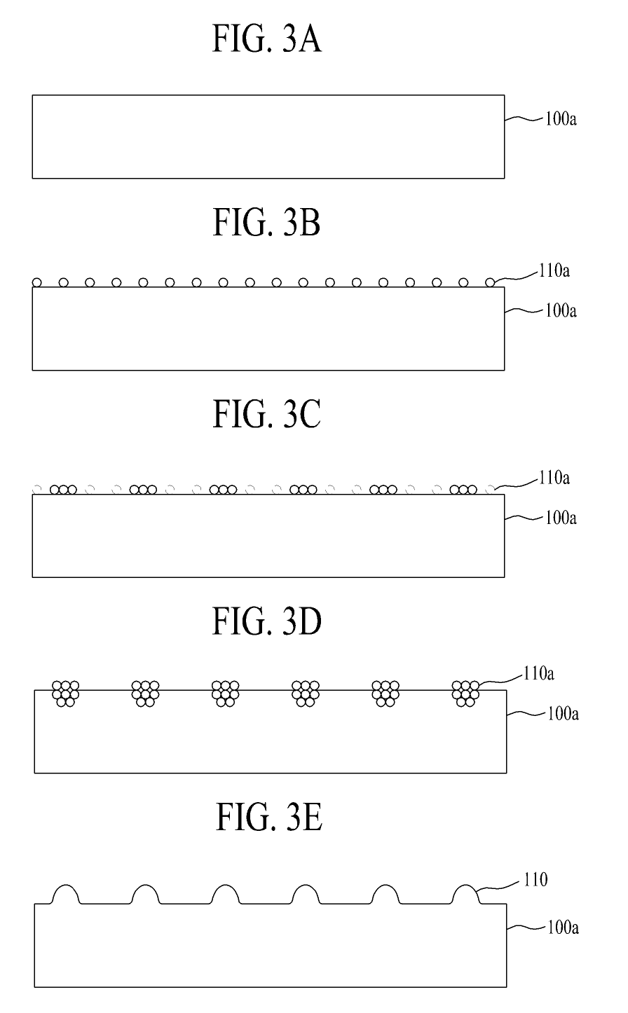

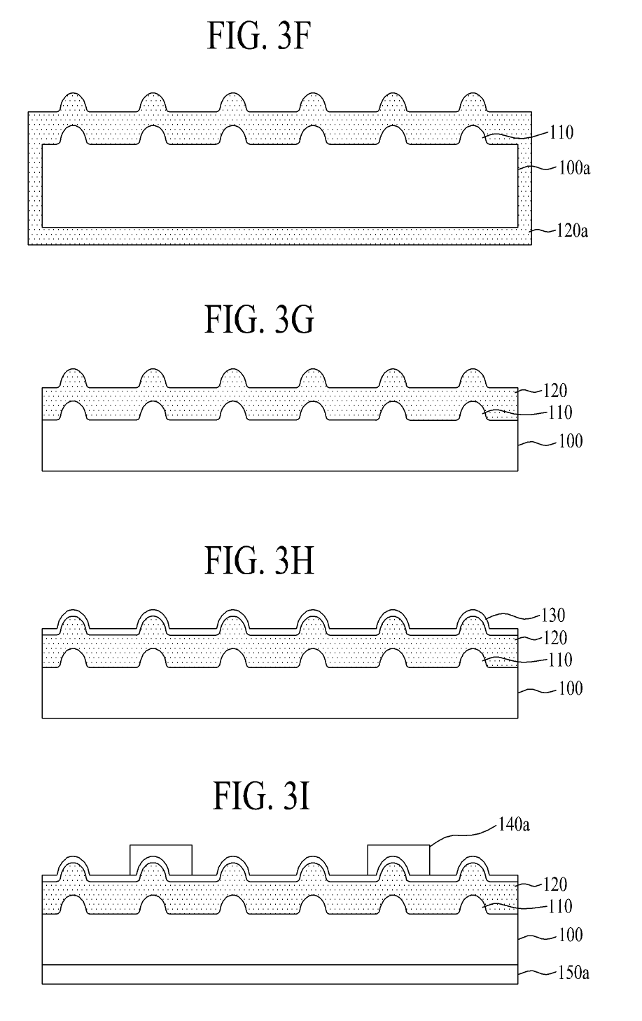

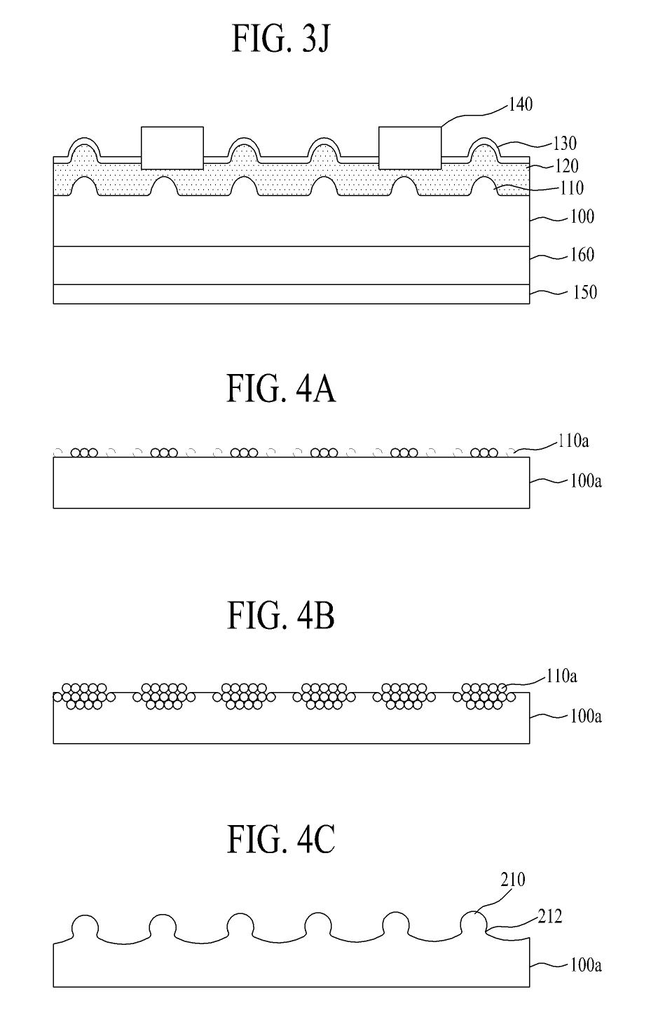

FIGS. 3A to 3J are cross section views illustrating a method for manufacturing the solar cell according to the first embodiment of the present invention.

First, as shown in FIG. 3A, the P-type semiconductor substrate 100a doped with the first dopant, for example, P-type dopant is prepared.

The P-type semiconductor substrate 100a may be manufactured by monocrystalline silicon or poly-crystalline silicon. The solar cell using the monocrystalline silicon can realize high efficiency since the monocrystalline silicon has a high degree of purity and a low crystal-defect density. However, the high-priced monocrystalline silicon is inappropriate for the mass production. In the meantime, efficiency of the solar cell using the poly-crystalline silicon is relatively lower than that of the solar cell using the monocrystalline silicon. However, the solar cell using the poly-crystalline silicon is appropriate for the mass production owing to the low-priced poly-crystalline silicon and inexpensive process cost.

Then, as shown in FIG. 3B, the plural silicon-based seeds 110a are formed on the surface of the P-type semiconductor substrate 100a.

The plural silicon-based seeds 110a are formed at fixed intervals on the surface of the P-type semiconductor substrate 100a by a low pressure chemical vapor deposition (LPCVD) or plasma deposition method. In this case, a flow rate of source gas may be 10 to 50 sccm.

Then, as shown in FIGS. 3C and 3D, after stopping the supply of source gas to a chamber (not shown), the heat-treatment process is carried out so that the seeds 110a are grown on the surface of the P-type semiconductor substrate 100a. As shown in FIG. 3E, the irregularity structure 110 is formed in the surface of the P-type semiconductor substrate 100a. At this time, the heat-treatment process is carried out at a temperature of about 600 to 700° C. for 5 to 90 seconds.

According as the heat-treatment process is carried out, surface atoms with high free energy in the P-type semiconductor substrate 100a, which are near to the seeds 110a, are moved toward the seeds 110a, and are crystallized, whereby the curved-line irregularity structure (for example, hemispheric-shaped irregularity structure) protrudes from the surface of the P-type semiconductor substrate 100a.

Before forming the irregularity structure 110 using the aforementioned seeds 110a, a planarization process for flattening the upper surface of the P-type semiconductor substrate 100a may be additionally carried out. Since the P-type semiconductor substrate 100a is manufactured by producing a semiconductor ingot, and slicing the produced semiconductor ingot through the use of saw, saw marks may remain in the surface of the P-type semiconductor substrate 100a. These saw marks can be removed by the planarization process. At this time, the planarization process may be carried out by dry etching, and more preferably, by using remote plasma source.

As shown in FIG. 3F, the second dopant, for example, N-type dopant is diffused in the P-type semiconductor substrate 100a with the irregularity structure 110, to thereby form an N-type semiconductor 120a in the surface of the P-type semiconductor substrate 100a.

The aforementioned doping process is carried out through a high-temperature diffusion process. In more detail, under the circumstance that the P-type semiconductor substrate 100a is placed in a furnace maintained at a high temperature more than 800° C., N-type dopant gas such as POCl₃ is supplied to the furnace, whereby the N-type dopant is diffused in the surface of the P-type semiconductor substrate 100a.

As shown in FIG. 3G, the first semiconductor layer, for example, N-type semiconductor 120a is removed from lateral and lower sides of the P-type semiconductor substrate 100a, thereby forming a PN junction layer including the P-type semiconductor layer 100 and the first semiconductor layer, for example, N-type semiconductor layer 120, wherein the N-type semiconductor layer 120 is positioned on the P-type semiconductor layer 100.

The N-type semiconductor 120a may be formed by a plasma ion doping method instead of the aforementioned high-temperature diffusion process.

For the plasma ion doping method, the P-type semiconductor substrate 100a is placed in a plasma generation apparatus, and then N-type dopant gas such as POCl₃ or PH₃ is supplied to the inside of the plasma generation apparatus so as to generate plasma. According as the plasma generates, phosphorous (P) ions included in the generated plasma are accelerated by RF electric field so that the upper surface of the P-type semiconductor substrate 100a is doped with the accelerated ions.

In comparison to the high-temperature diffusion process, the plasma ion doping method has the following advantages.

As compared with the high-temperature diffusion process, the plasma ion doping method can obtain the more precise doping with high realization through the precise control for doping density and depth by adjusting the gas flow or RF power. Also, the process time is decreased.

Since the ion doping proceeds at a vertical direction, the N-type semiconductor layer 120 is formed only on the upper surface of the P-type semiconductor substrate 100a. That is, there is no requirement for performing an additional process of removing the N-type semiconductor layer from the lateral and lower sides of the P-type semiconductor substrate 100a, to thereby result in the improved productivity.

As shown in FIG. 3H, the reflection-preventing layer 130 is formed on the N-type semiconductor layer 120.

According as the upper surface of the N-type semiconductor layer 120 is provided with the irregularity structure which is the same as the irregularity structure 110 formed in the P-type semiconductor layer 100, the reflection-preventing layer 130 is also formed with the irregularity structure.

The reflection-preventing layer 130 may be formed of silicon nitride or silicon oxide by a plasma CVD method.

As shown in FIG. 3I, the front electrode material 140a is formed at a predetermined pattern on the upper surface of the reflection-preventing layer 130; and the rear electrode material 150a is formed on the lower surface of the P-type semiconductor layer 100. The rear electrode material 150a may be formed at a predetermined pattern, which might be similar to the predetermined pattern of the front electrode material 140a.

The rear electrode material 150a may be formed before forming the front electrode material 140a, or after forming the front electrode material 140a.

The front electrode material 140a may be formed of a metal material, for example, Ag, Al, Ag+Al, Ag+Mg, Ag+Mn, Ag+Sb, Ag+Zn, Ag+Mo, Ag+Ni, or Ag+Cu, Ag+Al+Zn. The rear electrode material 150a may be formed of a predetermined material capable of functioning as P-type dopant such as Al-based material. For example, the rear electrode material 150a may be formed of a metal material such as Al, Al+Ag, Al+Mo, Al+Ni, Al+Cu, Al+Mg, Al+Mn, or Al+Zn.

The front electrode material 140a and rear electrode material 150a may be formed by a screen printing method, inkjet printing method, gravure printing method, or micro-contact printing method.

As shown in FIG. 3J, the front electrode 140, the second semiconductor layer such as the P+-type semiconductor layer 160, and the rear electrode 150 are formed by the heat-treatment process, to thereby complete the solar cell according to the present invention.

In more detail, when the heat-treatment process is carried out at a high temperature more than 850° C., the front electrode material permeates into the N-type semiconductor layer 120 through the reflection-preventing layer 130, whereby the front electrode 140 is electrically connected to the N-type semiconductor layer 120. Also, the rear electrode material permeates into the lower surface of the P-type semiconductor layer 100, the P⁺-type semiconductor layer 160 is formed in the rear surface of the P-type semiconductor substrate, whereby the rear electrode 150 is electrically connected to the P-type semiconductor layer 100 through the P⁺-type semiconductor layer 160.

In the aforementioned method for manufacturing the solar cell according to the first embodiment of the present invention, the hemispheric-shaped irregularity structure 110 is formed by growing the silicon-based seeds 110 on the P-type semiconductor substrate 100a, to thereby result in lowering of light-reflection ratio, and improvement of cell efficiency by the increased light dispersion.

FIGS. 4A to 4C are cross section views illustrating a procedure of forming an irregularity structure in the method for manufacturing the solar cell according to the second embodiment of the present invention.

As shown in FIG. 4A, a procedure of forming an irregularity structure 210 according to the second embodiment of the present invention includes steps of: stopping the supply of source gas to the chamber (not shown); growing the seeds 110a on the surface of the P-type semiconductor substrate 100a by carrying out the heat-treatment process at 600 to 700° C. for 90 to 120 seconds. Through the aforementioned steps, the irregularity structure 210 is formed in the surface of the P-type semiconductor substrate 100a, as shown in FIGS. 4B and 4C.

Owing to the increased time of the heat-treatment process according to the second embodiment of the present invention, more surface atoms with high free energy in the P-type semiconductor substrate 100a, which are near to the seeds 110a, are more moved toward the seeds 110a, and are crystallized, whereby the curved-line irregularity structure with neck portions may be formed in the surface of the P-type semiconductor substrate 100a. That is, the irregularity structure 210 is formed in such a way that the irregularity structure includes the hemispheric-shaped protruding portion and neck portion 212, wherein the hemispheric-shaped protruding portion protrudes from the P-type semiconductor substrate 100a, and the neck portion 212 is concaved in the lateral side of the hemispheric-shaped protruding portion. For example, the irregularity structure 210 according to the second embodiment of the present invention may be formed in shape of “Ω”.

Owing to the irregularity structure 210 according to the second embodiment of the present invention, the light-reflection ratio is lowered more, and the cell efficiency is improved more by the increased light dispersion.

The irregularity structure 110 according to the first embodiment of the present invention and the irregularity structure 210 according to the second embodiment of the present invention may be formed in such a way that they are formed in the hemispheric-shaped irregularity with the neck portion 212 or without the neck portion 212 by adjusting the time period of the heat-treatment process.

After forming the irregularity structure 210 according to the second embodiment of the present invention, the following steps for manufacturing the solar cell are identical to those of FIGS. 3F to 3J.

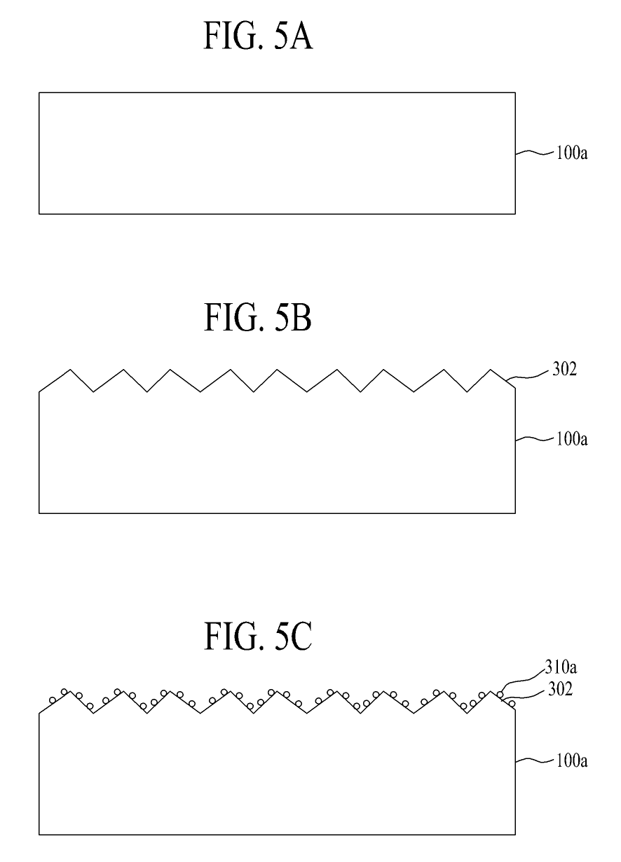

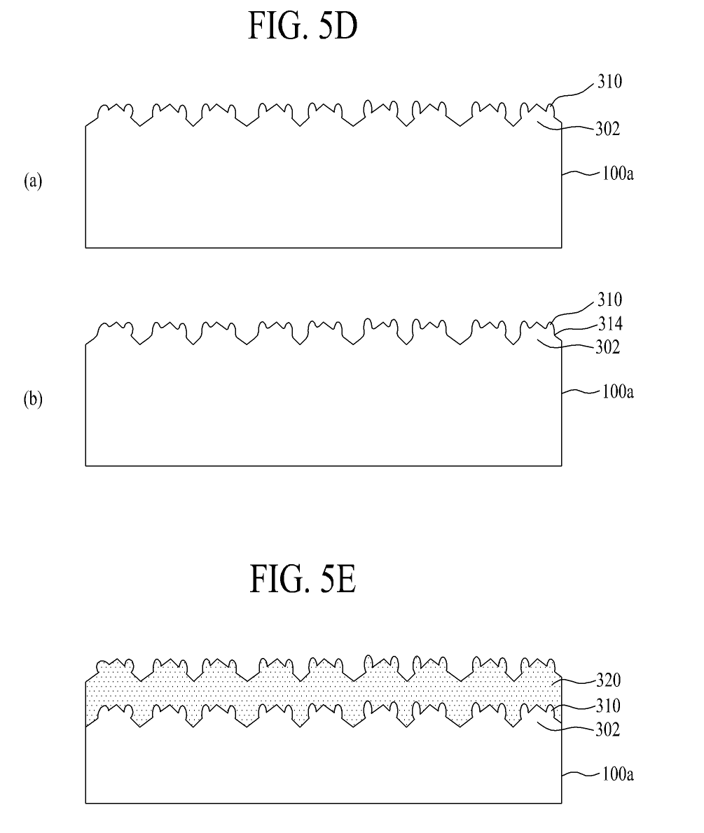

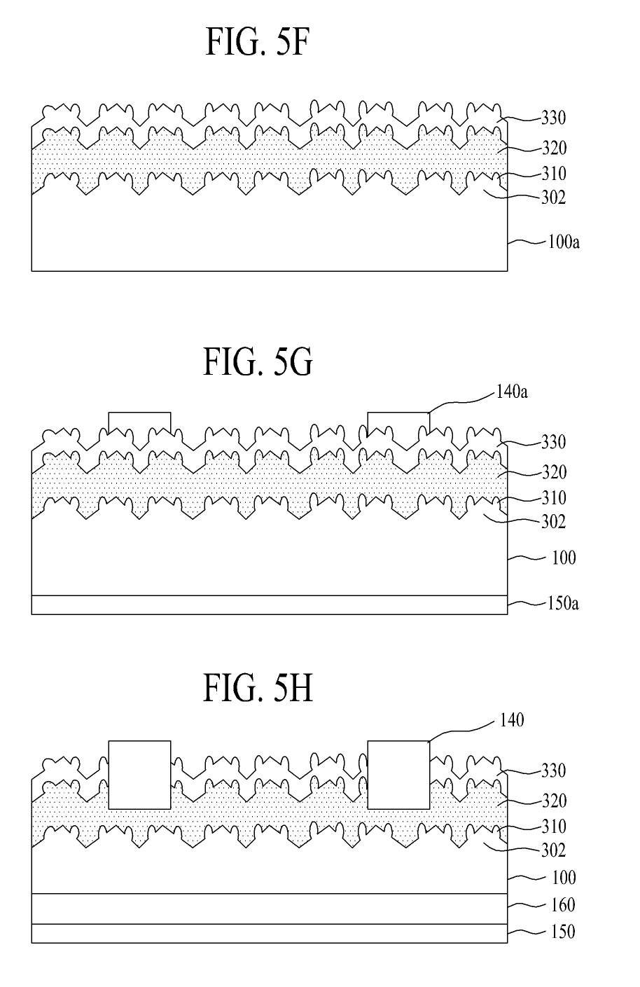

FIGS. 5A to 5H are cross section views illustrating a method for manufacturing the solar cell according to the second embodiment of the present invention.

First, as shown in FIG. 5A, the P-type semiconductor substrate 100a doped with the first dopant, for example, P-type dopant is prepared.

The P-type semiconductor substrate 100a may be manufactured by monocrystalline silicon or poly-crystalline silicon. The solar cell using the monocrystalline silicon can realize high efficiency since the monocrystalline silicon has a high degree of purity and a low crystal-defect density. However, the high-priced monocrystalline silicon is inappropriate for the mass production. In the meantime, efficiency of the solar cell using the poly-crystalline silicon is relatively lower than that of the solar cell using the monocrystalline silicon. However, the solar cell using the poly-crystalline silicon is appropriate for the mass production owing to the low-priced poly-crystalline silicon and inexpensive process cost.

As shown in FIG. 5B, the upper surface of the P-type semiconductor substrate 100a is etched to have the irregularity structure 102 therein. The etching process may be the wet etching or dry etching.

For the wet etching, the first-irregularity structure 302 is formed in the upper surface of the P-type semiconductor substrate 100a through the use of alkaline solution or acid solution.

The dry etching may use reactive ion etching (RIE).

The RIE enables the uniform irregularity structure 302 in the surface of the substrate without regard to the crystal orientation of crystal grains. If applying the RIE, a substrate-removed thickness is about 2˜3 μm, which is relatively smaller than that in the wet etching process. Also, the RIE is carried out by supplying a predetermined etching gas to a chamber, and generating plasma. Thus, the doping process as well as the etching process can be performed in the same chamber, which allows an In-Line process structure. The RIE uses an etching gas such as Cl₂, SF₆, NF₃, HBr, or mixture thereof; and may use an additional gas such as Ar, O₂, N₂, He, or mixture thereof.

Before the etching process for forming the irregularity structure 302 in the upper surface of the P-type semiconductor substrate 100a, a planarization process for flattening the upper surface of the P-type semiconductor substrate 100a may be additionally carried out. Since the P-type semiconductor substrate 100a is manufactured by producing a semiconductor ingot, and slicing the produced semiconductor ingot through the use of saw, saw marks may remain in the surface of the P-type semiconductor substrate 100a. If the RIE is applied to the P-type semiconductor substrate 100a with the saw marks, it might be difficult to obtain the uniform irregularity structure 302.

In this respect, the planarization process for flattening the upper surface of the P-type semiconductor substrate 100a is carried out before etching the upper surface of the P-type semiconductor substrate 100a to have the irregularity structure 302 therein, to thereby result in the uniform irregularity structure 302. Also, the planarization process can be applied to the lower surface of the P-type semiconductor substrate 100a as well as the upper surface of the P-type semiconductor substrate 100a. This planarization process may be carried out by dry etching, and more preferably, by using remote plasma source.

As shown in FIG. 5C, silicon-based seeds 310a are formed on the surface of the first-irregularity structure 302 formed in the P-type semiconductor substrate 100a.

The silicon-based seeds 310a are formed on the surface of the P-type semiconductor substrate 100 by a low pressure chemical vapor deposition (LPCVD) or plasma deposition method. In this case, a flow rate of source gas may be 10 to 50 sccm.

As shown in FIG. 5D, after stopping the supply of source gas to the chamber (not shown), the heat-treatment process is carried out so that the seeds 310a are grown on the surface of the first-irregularity structure 302, whereby the second-irregularity structure 310 is formed in the surface of the first-irregularity structure 302. This heat-treatment process may be carried out at a temperature of about 600 to 700° C. for 5 to 120 seconds.

According as the heat-treatment process is carried out, surface atoms with high free energy in the first-irregularity structure 302, which are near to the seeds 310a, are moved toward the seeds 310a, and are crystallized, whereby the second-irregularity structure 310 with the curved-line shape protrudes from the surface of the first-irregularity structure 302, as shown in (a) of FIG. 5D.

If the heat-treatment process is carried out for 90 to 120 seconds, the second-irregularity structure 310 is formed by the curved-line shape with the neck portion 314 protruding from the surface of the first-irregularity structure 302, as shown in (b) of FIG. 5D. In this case, the second-irregularity structure 310 may be formed in shape of “Ω”.

As shown in 5E, the surface of the P-type semiconductor substrate 100a is doped with the second dopant, for example, N-type dopant through the aforementioned high-temperature diffusion process or plasma ion-doping method, thereby forming the PN-junction layer including the P-type semiconductor layer 100 and the first semiconductor layer such as the N-type semiconductor layer 320, wherein the N-type semiconductor layer 320 is positioned on the P-type semiconductor layer 100.

As shown in FIG. 5F, the reflection-preventing layer 330 is formed on the N-type semiconductor layer 320.

According as the upper surface of the N-type semiconductor layer 320 is provided with the irregularity structure, the reflection-preventing layer 330 is also formed with the irregularity structure.

The reflection-preventing layer 330 may be formed of silicon nitride or silicon oxide by a plasma CVD method.

As shown in FIG. 5G, the front electrode material 140a is formed at a predetermined pattern on the upper surface of the reflection-preventing layer 330; and the rear electrode material 150a is formed on the lower surface of the P-type semiconductor layer 100. The rear electrode material 150a may be formed at a predetermined pattern, which might be similar to the predetermined pattern of the front electrode material 140a.

The rear electrode material 150a may be formed before forming the front electrode material 140a, or after forming the front electrode material 140a.

The front electrode material 140a may be formed of a metal material, for example, Ag, Al, Ag+Al, Ag+Mg, Ag+Mn, Ag+Sb, Ag+Zn, Ag+Mo, Ag+Ni, or Ag+Cu, Ag+Al+Zn. The rear electrode material 150a may be formed of a predetermined material capable of functioning as P-type dopant such as Al-based material. For example, the rear electrode material 150a may be formed of a metal material such as Al, Al+Ag, Al+Mo, Al+Ni, Al+Cu, Al+Mg, Al+Mn, or Al+Zn.

The front electrode material 140a and rear electrode material 150a may be formed by a screen printing method, inkjet printing method, gravure printing method, or micro-contact printing method.

As shown in FIG. 5H, the front electrode 140, the second semiconductor layer such as the P+-type semiconductor layer 160, and rear electrode 150 are formed by the heat-treatment process, to thereby complete the solar cell according to the present invention.

In more detail, when the heat-treatment process is carried out at a high temperature more than 850° C., the front electrode material 140a permeates into the N-type semiconductor layer 320 through the reflection-preventing layer 330, whereby the front electrode 140 is electrically connected to the N-type semiconductor layer 320. Also, the rear electrode material 150a permeates into the lower surface of the P-type semiconductor layer 100, the P⁺-type semiconductor layer 160 is formed in the rear surface of the P-type semiconductor substrate 100a, whereby the rear electrode 150 is electrically connected to the P-type semiconductor layer 100 through the P⁺-type semiconductor layer 160.

In the aforementioned method for manufacturing the solar cell according to the second embodiment of the present invention, the first-irregularity structure 302 is firstly formed in the P-type semiconductor substrate 100a, and then the silicon-based seeds 310a are formed on the surface of the first-irregularity structure 302. Thereafter, the silicon-based seeds 310a are grown thereon, to thereby form the second-irregularity structure 310. As a result, owing to the first-irregularity structure 302 and second-irregularity structure 310 according to the second embodiment of the present invention, the light-reflection ratio is lowered more, and the cell efficiency is improved more by the increased light dispersion.

The aforementioned solar cells according to the embodiments of the present invention disclose the process of forming the PN junction layer by doping the upper surface of the P-type semiconductor substrate with the N-type dopant on the basis of the P-type semiconductor substrate. However, it is not limited to the P-type semiconductor substrate. For example, the solar cell according to the present invention may use an N-type semiconductor substrate. That is, the solar cell according to the present invention may disclose the process of forming a PN junction layer by doping an upper surface of the N-type semiconductor substrate with P-type dopant.

A method for forming the PN junction layer by doping the upper surface of the N-type semiconductor substrate with the P-type dopant on the basis of the N-type semiconductor substrate will be explained in brief, wherein a detailed explanation for each process will be know from the aforementioned embodiments of the present invention.

First, after manufacturing the N-type semiconductor substrate doped with the second dopant, an irregularity structure is formed in the upper surface of the N-type semiconductor substrate.

The irregularity structure may be completed by forming seeds on the N-type semiconductor substrate, and growing the seeds therefrom, as shown in FIGS. 3B to 3E; or may be completed by forming a first-irregularity structure on the surface of the N-type semiconductor substrate, and forming a second-irregularity structure by forming seeds on the surface of the first-irregularity structure, and growing the seeds therefrom.

Then, the upper surface of the N-type semiconductor substrate with the irregularity structure is doped with first dopant, for example, P-type dopant, thereby forming a PN junction layer including an N-type semiconductor layer and P-type semiconductor layer, wherein the P-type semiconductor layer is positioned on the N-type semiconductor layer. The process of doping the P-type dopant may use gas containing P-type dopant, for example, B₂H₆.

Then, a reflection-preventing layer is formed on the P-type semiconductor layer.

After that, a predetermined pattern of front electrode material is formed on an upper surface of the reflection-preventing layer, and then a heat-treatment process is applied thereto. Thus, the front electrode material permeates into the P-type semiconductor layer through the reflection-preventing layer, to thereby form a front electrode electrically connected to the P-type semiconductor layer.

Then, a lower surface of the N-type semiconductor layer is doped with N-type dopant whose concentration is relatively higher than a normal concentration of the aforementioned N-type dopant, to thereby form an N⁺-type semiconductor layer. Thereafter, a rear electrode is formed in a lower surface of the N⁺-type semiconductor layer.

The N⁺-type semiconductor layer and rear electrode may be formed after forming the front electrode, or before forming the front electrode.

As mentioned above, the hemispheric-shaped irregularity structure is formed by growing the silicon-based seeds, whereby it is possible to lower the light-reflection ratio, and to improve the cell efficiency by the increased light dispersion.

Also, the surface area of the N-type semiconductor layer is increased owing to the first-irregularity structure and second-irregularity structure, to thereby result in lowering of the light-reflection ratio, and improvement of the cell efficiency by the increased light dispersion.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for manufacturing a solar cell comprising:
forming seeds in a predetermined surface portion of a semiconductor substrate doped with a first dopant, wherein the seeds are formed using a silicon source gas;
forming an irregularity structure on the semiconductor substrate by growing the seeds through a first heat-treatment process;
forming a first semiconductor layer doped with a second dopant in the semiconductor substrate with the irregularity structure, wherein the second dopant is different from the first dopant; and
forming a front electrode at one side of the semiconductor substrate, the front electrode electrically connected to the first semiconductor layer.

2. The method according to claim 1, wherein the first semiconductor layer is formed in the semiconductor substrate and an upper surface of the irregularity structure by doping the semiconductor substrate and the upper surface of the irregularity structure with the second dopant.

3. The method according to claim 1, wherein the first heat-treatment process is carried out at a temperature of 600 to 700° C. for 5 to 90 seconds so as to form the irregularity structure with a curved shape.

4. The method according to claim 1, wherein the first heat-treatment process is carried out at a temperature of 600 to 700° C. for 90 to 120 seconds so as to form the irregularity structure with a curved shape and having a neck portion.

5. The method according to claim 1, further comprising a reflection-preventing layer comprising silicon nitride, silicon oxynitride or silicon oxide on the first semiconductor layer,
wherein the front electrode is electrically connected to the first semiconductor layer through the reflection-preventing layer.

6. The method according to claim 5, wherein the reflection-preventing layer has an irregularity structure which is identical in position and shape to the irregularity structure on the first semiconductor layer.

7. The method according to claim 1, wherein the first dopant is a P-type or N-type dopant.

8. The method according to claim 1, further comprising:
forming a rear electrode at an opposite side of the semiconductor substrate; and
forming a second semiconductor layer at the opposite side of the semiconductor substrate through a second heat-treatment process, the second semiconductor layer doped with the first dopant at a concentration that is relatively higher than that of the first dopant in the semiconductor substrate;
wherein the rear electrode is electrically connected to the semiconductor substrate through the second semiconductor layer.

9. The method according to claim 1, wherein the silicon source gas comprises SiH₄ or Si₂H₆.

10. A method for manufacturing a solar cell comprising:
forming a first-irregularity structure on a surface of a semiconductor substrate doped with a first dopant;
forming a second-irregularity structure on the first-irregularity structure;
forming a first semiconductor layer doped with a second dopant in the semiconductor substrate with the first-irregularity structure and second-irregularity structure, wherein the second dopant is different from the first dopant; and
forming a front electrode at one side of the semiconductor substrate, the front electrode electrically connected to the first semiconductor layer.

11. The method according to claim 10, wherein the first semiconductor layer is formed in the semiconductor substrate and upper surfaces of the first-irregularity structure and second-irregularity structure by doping the semiconductor substrate and upper surfaces of the first-irregularity structure and second-irregularity structure with the second dopant.

12. The method according to claim 10, further comprising:
forming a reflection-preventing layer comprising silicon nitride, silicon oxynitride or silicon oxide on the first semiconductor layer;
wherein the front electrode is electrically connected to the first semiconductor layer through the reflection-preventing layer.

13. The method according to claim 10, wherein the first dopant is a P-type or N-type dopant.

14. The method according to claim 10, further comprising:
forming a rear electrode at an opposite side of the semiconductor substrate; and
forming a second semiconductor layer at the opposite side of the semiconductor substrate through a first heat-treatment process, the second semiconductor layer doped with the first dopant at a concentration that is relatively higher than that of the first dopant in the semiconductor substrate;
wherein the rear electrode is electrically connected to the semiconductor substrate through the second semiconductor layer.

15. The method according to claim 10, wherein forming the first-irregularity structure comprises wet etching or dry etching.

16. The method according to claim 10, wherein the first-irregularity structure has a mountain or peaked shape.

17. The method according to claim 10, wherein forming the second-irregularity structure on the first-irregularity structure comprises:
forming seeds on the first-irregularity structure using a silicon source gas; and
forming the second-irregularity structure by growing the seeds on the first-irregularity structure using a second heat-treatment process.

18. The method according to claim 10, wherein the silicon source gas comprises SiH₄ or Si₂H₆.

19. The method according to claim 17, wherein the second heat-treatment process is carried out at a temperature of 600 to 700° C. for 5 to 90 seconds so as to form the second-irregularity structure with a curved shape.

20. The method according to claim 17, wherein the second heat-treatment process is carried out at a temperature of 600 to 700° C. for 90 to 120 seconds so as to form the second-irregularity structure with a curved shapes having a neck portion.

21. A solar cell comprising:
a semiconductor substrate doped with a first dopant;
an irregularity structure on the semiconductor substrate;
a first semiconductor layer doped with a second dopant in the semiconductor substrate with the irregularity structure, wherein the second dopant is different from the first dopant; and
a front electrode electrically connected to the first semiconductor layer,
wherein the irregularity structure has a curved shape, or a curved shape with a neck portion.

22. The solar cell according to claim 21, further comprising a reflection-preventing layer comprising silicon nitride, silicon oxynitride or silicon oxide on the first semiconductor layer;
wherein the front electrode is electrically connected to the first semiconductor layer through the reflection-preventing layer.

23. The solar cell according to claim 22, wherein the reflection-preventing layer has an irregularity structure which is identical in position and shape to the irregularity structure in the first semiconductor layer.

24. The solar cell according to claim 21, wherein the first dopant is a P-type or N-type dopant.

25. The solar cell according to claim 21, further comprising:
a rear electrode at an opposite side of the semiconductor substrate; and
a second semiconductor layer at the opposite side of the semiconductor substrate, the second semiconductor layer doped with the first dopant at a concentration that is relatively higher than that of the first dopant in the semiconductor substrate;
wherein the rear electrode is electrically connected to the semiconductor substrate through the second semiconductor layer.

26. A solar cell comprising:
a semiconductor substrate doped with a first dopant;
a first-irregularity structure on the semiconductor substrate;
a second-irregularity structure on the first-irregularity structure;
a first semiconductor layer doped with a second dopant in the semiconductor substrate with the first-irregularity structure and second-irregularity structure, wherein the second dopant is different from the first dopant; and
a front electrode electrically connected to the first semiconductor layer.

27. The solar cell according to claim 26, further comprising a reflection-preventing layer comprising silicon nitride, silicon oxynitride or silicon oxide on the first semiconductor layer;
wherein the front electrode is electrically connected to the first semiconductor layer through the reflection-preventing layer.

28. The solar cell according to claim 26, wherein the first dopant is a P-type or N-type dopant.

29. The solar cell according to claim 26, further comprising:
a rear electrode at an opposite side of the semiconductor substrate; and
a second semiconductor layer at the opposite side of the semiconductor substrate, the second semiconductor layer doped with the first dopant at a concentration that is relatively higher than that of the first dopant used in the semiconductor substrate;
wherein the rear electrode is electrically connected to the semiconductor substrate through the second semiconductor layer.

30. The solar cell according to claim 26, wherein the first-irregularity structure has a mountain or peaked shape.

31. The solar cell according to claim 26, wherein the second-irregularity structure protrudes from the surface of the first-irregularity structure and has a curved shape or curved shape having a neck portion.
